(19) United States
(12) Patent Application Publication
(10) Pub. No.: US 2024/0006281 A1
(43) Pub. Date: Jan. 4, 2024

(54) SEMICONDUCTOR STRUCTURE, PACKAGING DEVICE AND METHOD FOR MANUFACTURING SEMICONDUCTOR STRUCTURE

(71) Applicant: CHANGXIN MEMORY TECHNOLOGIES, INC., Hefei City (CN)

(72) Inventor: Zongzheng LU, Hefei City (CN)

(73) Assignee: CHANGXIN MEMORY TECHNOLOGIES, INC., Hefei City (CN)

(21) Appl. No.: 18/157,079

(22) Filed: Jan. 20, 2023

Related U.S. Application Data
(63) Continuation of application No. PCT/CN2022/105548, filed on Jul. 13, 2022.

(30) Foreign Application Priority Data
Jul. 4, 2022 (CN) 202210787178.X

(51) Int. Cl. H01L 23/498; H01L 21/48; H01L 23/31

(52) U.S. Cl. CPC H01L 23/49816; H01L 21/4853; H01L 23/3128

(57) ABSTRACT

A semiconductor structure includes: a substrate including a first surface; a first solder pad located on the first surface; a transferring part located on the first solder pad, in which the transferring part includes a first subpart covering the first solder pad and a second subpart covering the first subpart, and orthographic projections of the first subpart and the first solder pad on the first surface fall within an orthographic projection of the second subpart on the first surface; and a solder ball located on the second subpart.

### CROSS-REFERENCE TO RELATED APPLICATIONS

This is a continuation of International Application No. PCT/CN2022/105548 filed on Jul. 13, 2022, which claims priority to Chinese Patent Application No. 202210787178.X filed on Jul. 4, 2022. The disclosures of the above-referenced applications are hereby incorporated by reference in their entirety.

### BACKGROUND

A semiconductor structure, such as a packaging substrate, typically includes a substrate, on a surface of which is provided solder pads for soldering solder balls and a signal transmission lines between the solder pads.

However, since the size of solder balls is large, and the sizes of solder pads and the solder balls is equal or close, the area occupied by solder pads and solder balls on the surface of the substrate is large, so that the area occupied by signal transmission lines on the surface of the substrate is squeezed, resulting in that the signal transmission lines are designed thin and easy to break. Moreover, in order to avoid the solder pads, the signal transmission lines often have a long winding, which leads to signal integrity problems.

### SUMMARY

The disclosure relates to the field of semiconductor manufacturing, and in particular to a semiconductor structure, a packaging device and a method for manufacturing a semiconductor structure.

Embodiments of the disclosure provide a semiconductor structure, which includes a substrate, a first solder pad, a transferring part and a solder ball.

The substrate includes a first surface.

The first solder pad is located on the first surface.

The transferring part is located on the first solder pad, and the transferring part includes a first subpart covering the first solder pad and a second subpart covering the first subpart. Orthographic projections of the first subpart and the first solder pad on the first surface fall within an orthographic projection of the second subpart on the first surface.

The solder ball is located on the second subpart.

Embodiments of the disclosure further provide a packaging device including at least one chip and any semiconductor structure as described above. The at least one chip is bonded to the semiconductor structure.

Embodiments of the disclosure further provide a method for manufacturing a semiconductor structure, which includes the following operations.

A substrate including a first surface is provided.

A first solder pad is formed on the first surface.

A transferring part is formed on the first solder pad. The transferring part includes a first subpart covering the first solder pad and a second subpart covering the first subpart. Orthographic projections of the first subpart and the first solder pad on the first surface fall within an orthographic projection of the second subpart on the first surface.

A solder ball is formed on the second subpart.

### BRIEF DESCRIPTION OF THE DRAWINGS

In order to more clearly illustrate the technical solutions of the embodiments of the disclosure, a brief description of the accompanying drawings used in the embodiments will be provided below. It is apparent that the drawings in the following description are merely some embodiments of the disclosure. For a person of ordinary skill in the art, other drawings can be obtained based on these drawings without creative work.

FIG. 1 is a schematic diagram of a semiconductor structure provided by an embodiment of the disclosure;

FIG. 2 is a schematic diagram of a semiconductor structure provided by another embodiment of the disclosure;

FIG. 3 is a schematic diagram of a semiconductor structure provided by yet another embodiment of the disclosure;

FIG. 4 is a schematic diagram of a packaging device provided by an embodiment of the disclosure;

FIG. 5 is a flowchart showing a method for manufacturing a semiconductor structure provided by an embodiment of the disclosure;

FIG. 6 is a first process flow diagram showing a method for manufacturing a semiconductor structure provided by an embodiment of the disclosure;

FIG. 7 is a second process flow diagram showing a method for manufacturing a semiconductor structure provided by an embodiment of the present disclosure;

FIG. 8 is a third process flow diagram showing a method for manufacturing a semiconductor structure provided by an embodiment of the present disclosure;

FIG. 9 is a fourth process flow diagram showing a method for manufacturing a semiconductor structure provided by an embodiment of the present disclosure;

FIG. 10 is a fifth process flow diagram showing a method for manufacturing a semiconductor structure provided by an embodiment of the present disclosure;

FIG. 11 is a sixth process flow diagram showing a method for manufacturing a semiconductor structure provided by an embodiment of the present disclosure;

FIG. 12 is a seventh process flow diagram showing a method for manufacturing a semiconductor structure provided by an embodiment of the present disclosure;

FIG. 13 is a first process flow diagram showing a method for manufacturing a semiconductor structure provided by another embodiment of the disclosure;

FIG. 14 is a second process flow diagram showing a method for manufacturing a semiconductor structure provided by another embodiment of the present disclosure;

FIG. 15 is a third process flow diagram showing a method for manufacturing a semiconductor structure provided by another embodiment of the present disclosure;

FIG. 16 is a fourth process flow diagram showing a method for manufacturing a semiconductor structure provided by another embodiment of the present disclosure; and

FIG. 17 is a process flow diagram showing a method for manufacturing a semiconductor structure provided by yet another embodiment of the disclosure.

### DETAILED DESCRIPTION

Exemplary implementations of the present disclosure will be described in more detail below with reference to the accompanying drawings. Although exemplary implementations of the present disclosure are shown in the drawings, it should be understood that the present disclosure may be implemented in various forms and should not be limited to the specific implementations set forth herein. Instead, these embodiments are provided so that the disclosure will be more thoroughly understood and the scope of the disclosure will be fully conveyed to those skilled in the art.

In the description hereinbelow, numerous specific details are given to provide a more thorough understanding of the disclosure. However it will be apparent to those skilled in the art that the disclosure may be implemented without one or more of these details. In other examples, some technical features well-known in the art are not described in order to avoid confusion with the present disclosure; that is, not all of the features of actual embodiments are described herein, and well-known functions and structures are not described in detail.

In the drawings, the dimensions of layers, regions, elements and their relative dimensions may be exaggerated for clarity. The same reference numeral denotes the same element throughout the text.

It should be understood that when an element or a layer is referred to as being “on”, “adjacent to”, “connected to” or “coupled to” another element or layer, it may be directly on the other element or layer, adjacent to the other element or layer, or connected to or coupled to the other element or layer, or there may be an intermediate element or layer therebetween. In contrast, when an element is referred to as being “directly on”, “directly adjacent to”, “directly connected to” or “directly coupled to” another element or layer, there is no intermediate element or layer therebetween. It should be understood that although the terms “first”, “second”, “third” and the like may be used to describe various elements, components, regions, layers, and/or portions, these elements, components, regions, layers, and/or portions should not be limited by these terms. These terms are only used to distinguish one element, component, region, layer or portion from another element, component, region, layer or portion. Therefore, without departing from the teaching of the present disclosure, a first element, component, region, layer or portion discussed hereinafter may be expressed as a second element, component, region, layer or portion. While discussing a second element, component, region, layer or portion, it does not imply that a first element, component, region, layer or portion is necessarily present in the present disclosure.

Spatial relationship terms such as “beneath”, “below”, “under”, “lower”, “above”, or “upper” and the like may be used herein for convenience to describe a relationship between one element or feature and another element or feature shown in the drawings. It should be understood that, the spatial relationship terms are intended to further include different orientations of a device in use and operation in addition to the orientations shown in the drawings. For example, if the device in the drawings is turned over, an element or feature described as being “below” or “under” or “beneath” another element will be oriented as being “above” the other element or feature. Therefore, the exemplary terms “below” and “under” may include both orientations, above and under. The device may also include additional orientations (e.g., rotated by 90 degrees or other orientations), and the spatial terms used herein are interpreted accordingly.

The terms used herein are intended to describe specific embodiments only and are not to be a limitation to the present disclosure. As used herein, the singular forms “a”, “an”, and “the/said” are intended to include the plural forms as well, unless the context clearly dictates otherwise. It should be further understood that the terms “consist of” and/or “include”, as used in the specification, determine the presence of the stated features, integers, steps, operations, elements and/or components are present, but do not exclude the presence or addition of one or more other features, integers, steps, operations, elements, components and/or groups. As used herein, the term “and/or” includes any and all combinations of the related listed items.

A semiconductor structure, such as a packaging base, typically includes a substrate, on a surface of which is provided solder pads for soldering solder balls and a signal transmission line between the solder pads.

However, since the size of solder balls is large and the sizes of solder pads and the solder balls is equal or close, the area occupied by solder pads and solder balls on the surface of the substrate is large, so that the area occupied by signal transmission lines on the surface of the substrate is squeezed, which makes the signal transmission lines are designed thin and easy to break. Moreover, in order to avoid the solder pads, the signal transmission lines often have a long winding, which leads to signal integrity problems.

On the basis of this, the following technical solution of the embodiments of the disclosure is proposed. Specific embodiments of the disclosure will be described in detail below with reference to the figures. In detailing the embodiments of the disclosure, the schematic diagrams may be partially enlarged not in accordance with a general scale for convenience of description, and the schematic diagrams are only provided as examples, and are not intend to limit the protection scope of the disclosure herein.

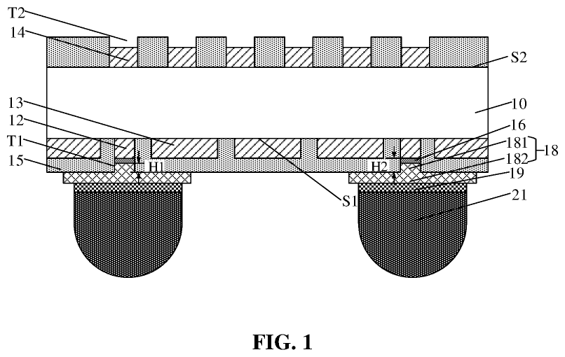

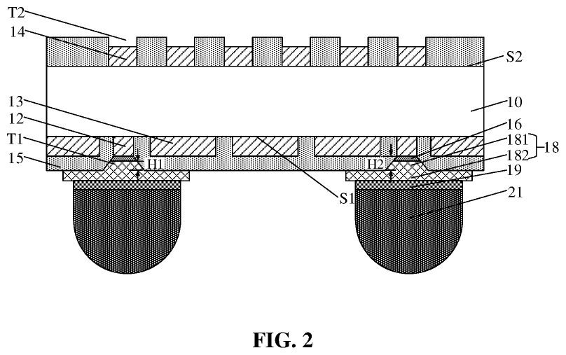

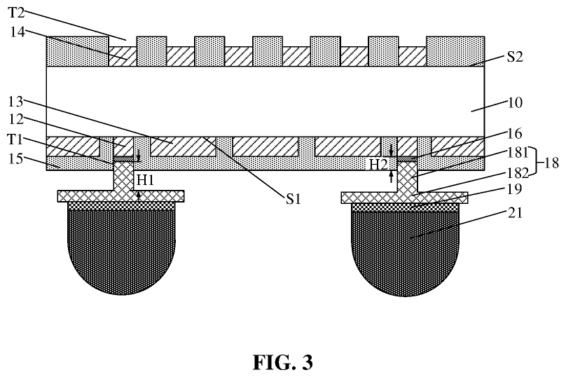

FIG. 1 is a schematic diagram of a semiconductor structure provided by an embodiment of the disclosure; FIG. 2 is a schematic diagram of a semiconductor structure provided by another embodiment of the disclosure; and FIG. 3 is a schematic diagram of a semiconductor structure provided by yet another embodiment of the disclosure. The semiconductor structure provided by embodiments of the disclosure will be further described below in combination with FIG. 1 to FIG. 3.

As shown in the figures, the semiconductor structure includes a substrate 10 including a first surface S1; a first solder pad 12 located on the first surface S1; a transferring part 18 located on the first solder pad 12, in which the transferring part 18 includes a first subpart 181 covering the first solder pad 12 and a second subpart 182 covering the first subpart 181, and the orthographic projections of the first subpart 181 and the first solder pad 12 on the first surface S1 fall within the orthographic projection of the second subpart 182 on the first surface S1; and a solder ball 21 located on the second subpart 182.

In practice, the semiconductor structure provided by embodiments of the disclosure may be a packaging base, such as a ball gate array (BGA) packaging base, but is not limited thereto. The semiconductor structure may also be any semiconductor structure including a solder ball.

The material of the substrate 10 may be an organic insulating material, a fiber-blended organic insulating material, a particle-blended organic insulating material or the like, such as epoxy resin, polyimide, bismaleimide/triazine-based resin, cyanate resin or a composite of glass fiber thereof or the like, but is not limited thereto. The material of the substrate 10 may also be a semiconductor material such as silicon. In some embodiments, conductive through-holes (not shown) are formed in the substrate 10.

There are a plurality of first solder pads 12, a plurality of transferring parts 18, and a plurality of solder balls 21. The plurality of solder balls 21 are electrically connected to the plurality of first solder pads 12 in one-to-one correspondence through the transferring parts 18. In some embodiments, the semiconductor structure further includes transmission lines 13 located on the first surface S1 and arranged between the plurality of first solder pads 12 for transmitting electrical signal. In the embodiments of the disclosure, the orthographic projections of the first subpart 181 and the first solder pad 12 on the first surface S1 fall within the orthographic projection of the second subpart 182 on the first surface S1, and the solder ball 21 is soldered to the second subpart 182 having a larger size. In this way, without changing the size of the solder ball 21, the area occupied by the first solder pad 12 on the first surface S1 can be reduced by reducing the size of the first solder pad 12, thereby allowing the transmission lines 13 to occupy a larger area on the first surface S1. Thus, the transmission lines 13 can be designed to be wider, so that the breakage risk of transmission line 13 is reduced or eliminated, avoiding electromagnetic interference and signal crosstalk caused by a too close distance of the transmission lines. In addition, the problem of long transmission path of the transmission lines 13 can be avoided or alleviated due to the small size of the first solder pad 12.

As shown in FIG. 1, in an embodiment, the first subpart 181 has a uniform width in a direction perpendicular to the first surface S1 and from the first solder pad 12 to the second subpart 182. In some embodiments, the orthographic projection of the first subpart 181 on the first surface S1 completely coincides with the orthographic projection of the first solder pad 12 on the first surface S1, or the orthographic projection of the first subpart 181 on the first surface S1 falls within the orthographic projection of the first solder pad 12 on the first surface S1, that is, the cross-sectional area of the first subpart 181 is less than or equal to the cross-sectional area of the first solder pad 12, thereby avoiding a short circuit caused by the contact of the first subpart 181 with the transmission line 13 due to an oversize of the first subpart 181.

But there is not limited to this. As shown in FIG. 2, in another embodiments, in a direction perpendicular to the first surface S1 and from the first solder pad 12 to the second subpart 182, the width of the first subpart 181 gradually increases. Thus, the contact area between the first subpart 181 and the second subpart 182 is increased, reducing the contact resistance to achieve better signal transmission, and preventing the first subpart 181 from coming into contact with the transmission line 13 due to the oversize of the side close to the first solder pad 12. In some embodiments, the first solder pad 12 is shaped as a cylinder. The first solder pad 12 has a diameter between 20 m and 420 m, and a thickness between 15 m and 30 m. When the diameter of the first solder pad 12 is small, for example, less than 50 m, in a direction perpendicular to the first surface S1 and from the first solder pad 12 to the second subpart 182, the width of the first subpart 181 may be designed to gradually increase to achieve better signal transmission, avoiding the influence of signal transmission due to a too small size of the first solder pad 12.

The ratio of the cross-sectional area of the second subpart 182 to the cross-sectional area of the first solder pad 12 should not be too large or too small. If the ratio is too large, the cross-sectional area of the first solder pad 12 is too small, and the contact area between the first solder pad 12 and the transferring part 18 is small, which increases the contact resistance, thereby leading to a poor signal transmission effect of the first solder pad 12. If the ratio is too small, the difference between the cross-sectional area of the first solder pad 12 and the cross-sectional area of the second subpart 182 is too small, and the size reduction of the first solder pad 12 is not effective, so that a large wiring area cannot be reserved for the transmission lines 13. In an embodiment, the ratio of the cross-sectional area of the second subpart 182 to the cross-sectional area of the first solder pad 12 is between 2 and 50, for example, between 2 and 16, but is not limited to thereto. The ratio of the cross-sectional area of the second subpart 182 to the cross-sectional area of the first solder pad 12 may be larger, for example between 50 and 100. In some embodiments, the second subpart 182 and the first solder pad 12 are both shaped as cylinder, and the ratio of the diameter of the second subpart 182 to the diameter of the first solder pad 12 ranges from 1.1 to 7, for example, from 1.4 to 4, but is not limited to thereto. The ratio of the diameter of the second subpart 182 to the diameter of the first solder pad 12 may be larger, for example, between 7 and 10.

In some embodiments, the orthographic projection of the solder ball 21 on the first surface S1 completely coincides with the orthographic projection of the second subpart 182 on the first surface S1, or the orthographic projection of the solder ball 21 on the first surface S1 falls within the orthographic projection of the second subpart 182 on the first surface S1. That is, the cross-sectional dimension of the second subpart 182 is greater than or equal to the cross-sectional dimension of the solder ball 21, which allows the solder ball 21 and the second subpart 182 to have a larger contact area, thereby reducing the contact resistance, and contributing to a firmer soldering of the solder ball 21 and the second subpart 182. In some embodiments, the second subpart 182 is shaped as a cylinder. The ratio of the diameter of the second subpart 182 to the diameter of the solder ball 21 is between 1 and 1.2, for example, is 1.1. In some embodiments, the second subpart 182 has a diameter between 40 m and 510 m and a thickness between 10 m and 20 m. The diameter of the solder ball 21 has a diameter between 40 m and 420 m.

The material of the first subpart 181 and the material of the second subpart 182 may be the same or different, and the materials of the first solder pad 12 and the transmission line 13 may be the same or different. The materials of the first subpart 181, the second subpart 182, the first solder pad 12, and the transmission line 13 include tungsten (W), copper (Cu), titanium (Ti), tantalum (Ta), nickel (Ni), chromium (Cr), gold (Au), silver (Ag), titanium nitride (TiN), tantalum nitride (TaN), a metal silicide, a metal alloy, or any combination thereof. In some embodiments, the material of the first subpart 181 is the same as that of the second subpart 182, for example, both are copper. The material of the first solder pad 12 is the same as that of the transmission lines 13, for example, both are copper. The solder ball 21 may be a lead-containing or lead-free solder ball.

In some embodiments, the semiconductor structure further includes a composite enhancing layer 16 located between the first subpart 181 and the first solder pad 12. The material of the composite enhancing layer 16 may be an alloy material such as titanium which has the advantages of good electrical conductivity, high strength, easy welding and the like and plays a good bonding role, but is not limited to thereto. Any material that meets the above requirements may be used as the composite enhancing layer 16 in the embodiments of the disclosure.

In some embodiments, the semiconductor structure further includes a solderable layer 19 located between the solder ball 21 and the second subpart 182. The solderable layer 19 facilitates a firmer soldering of the solder ball 21 and the second subpart 182. The material of the side of the solderable layer 19 adjacent to the solder ball 21 may be tin (Sn), gold (Au) or silver (Ag).

In some embodiments, the semiconductor structure further includes a dielectric layer 15 covering the transmission line 13 and filling a gap between the first solder pad 12 and the transmission line 13 for protecting the transmission line 13 and the first solder pad 12 from being oxidized or damaged. The material of the dielectric layer 15 may be graphene, ink, green paint, epoxy resin or the like, for example solder mask (green oil).

In some embodiments, a first opening T1 exposing the first solder pad 12 is formed in the dielectric layer 15. As shown in FIG. 1 or FIG. 2, in some embodiments, the first subpart 181 is located in the first opening T1, and the second subpart 182 covers the first subpart 181 and part of the dielectric layer 15. More specifically, the height H1 of the first subpart 181 is equal to or less than the height H2 of the first opening T1, but is not limited to thereto. As shown in FIG. 3, in other embodiments, the first subpart 181 is partially located in the first opening T1, the height H1 of the first subpart 181 is greater than the height H2 of the first opening T1, and the second subpart 182 is farther from the transmission line 13. In this way, the signal interference between the second subpart 182 and the transmission line 13 can be reduced when the semiconductor structure is in operation.

In some embodiments, the semiconductor structure further includes a plurality of second solder pads 14 located on a second surface S2 of the substrate 10 opposite to the first surface S1. The dielectric layer 15 further fills gaps between the plurality of second solder pads 14, in which a plurality of second openings T2 that expose the second solder pads are formed in the dielectric layer 15, and the second solder pads 14 can be used for subsequent connection to other structures. But there is not limited to this, in some other embodiments, the upper surface of the dielectric layer 15 may also be flush with the upper surface of the second solder pads 14, or the dielectric layer 15 located between the plurality of second solder pads 14 may be removed, thus facilitating the connection of the second solder pads 14 to other structures in actual operation, and the embodiments of the disclosure do not limit this too much.

In some embodiments, the first solder pad 12 and the transmission line 13 on the first surface S1 are electrically connected with the second solder pads 14 on the second surface S2 through conductive through-holes (not shown) located in the substrate 10. The material of the second solder pads 14 and the material of the first solder pad 12 may be the same or different. In some embodiments, the material of the second solder pads 14 is the same as the material of the first solder pad 12, for example, both are copper.

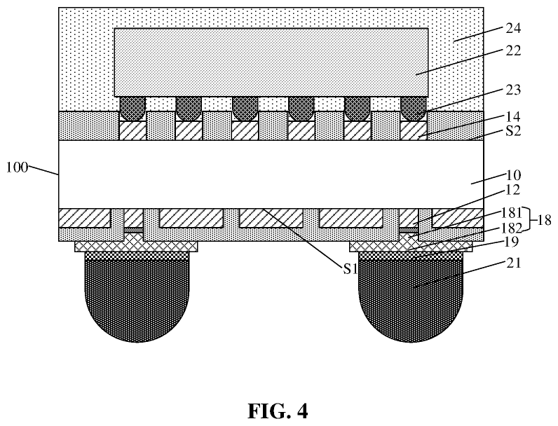

Embodiments of the disclosure further provide a packaging device. As shown in FIG. 4, the packaging device includes at least one chip 22 and any semiconductor structure 100 as described above, in which the at least one chip 22 is bonded to the semiconductor structure 100.

Specifically, the semiconductor structure 100 includes a substrate 10 including a first surface S1; a first solder pad 12 located on the first surface S1; a transferring part 18 located on the first solder pad 12, in which the transferring part 18 includes a first subpart 181 covering the first solder pad 12 and a second subpart 182 covering the first subpart 181, and the orthographic projections of the first subpart 181 and the first solder pad 12 on the first surface S1 fall within the orthographic projection of the second subpart 182 on the first surface S1; and a solder ball 21 located on the second subpart 182. In some embodiments, the semiconductor structure 100 further includes a plurality of second solder pads 14 located on a second surface S2 of the substrate 10 opposite the first surface S1.

In some embodiments, the number of the chip 22 may be one. The packaging device further includes bumps 23 arranged between the chip 22 and the semiconductor structure 100. A plurality of bumps 23 are connected to a plurality of second solder pads 14 in one-to-one correspondence. The material of the bumps 23 includes copper. But there is not limited to this, in other embodiments, there is a plurality of chips 22, and the plurality of chips 22 are stacked in the vertical direction, and bonded to each other. The chip 22 may also be connected to the second solder pads 14 through a bonding wire.

In some embodiments, the packaging device further includes a packaging layer 24 covering at least the chip 22 and the second surface S2 of the substrate 10. The material of the package layer 24 includes an epoxy resin molding compound.

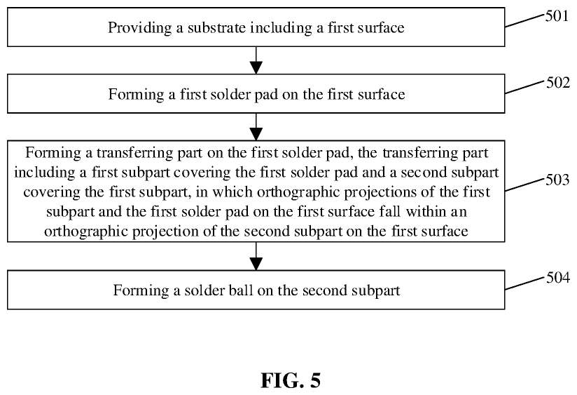

Embodiments of the disclosure further provide a method for manufacturing a semiconductor structure, as shown in FIG. 5, the method includes the following operations.

In S501, a substrate including a first surface is provided.

In S502, a first solder pad is formed on the first surface.

In S503, a transferring part is formed on the first solder pad. The transferring part includes a first subpart covering the first solder pad and a second subpart covering the first subpart. The orthographic projections of the first subpart and the first solder pad on the first surface fall within the orthographic projection of the second subpart on the first surface.

In S504, a solder ball is formed on the second subpart.

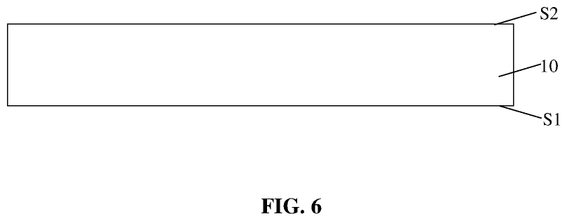

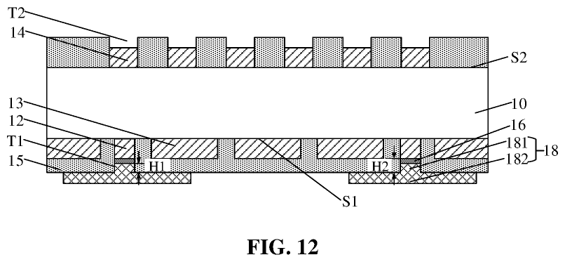

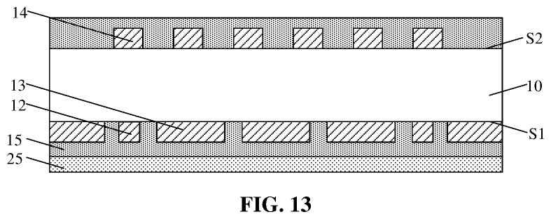

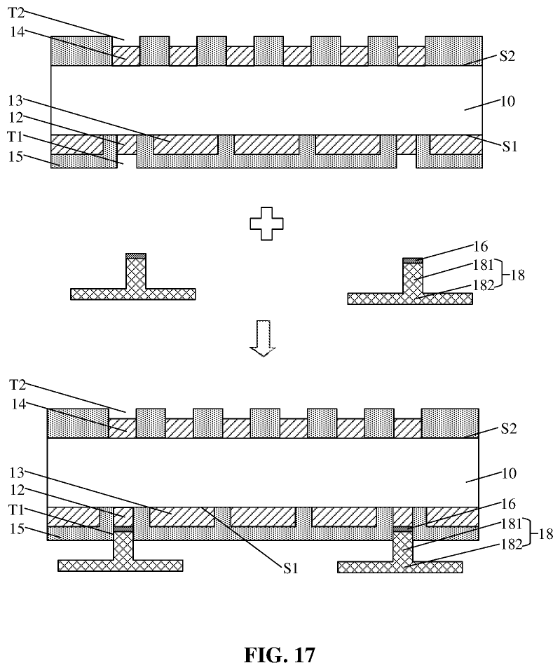

The method for manufacturing a semiconductor structure according to embodiments of the disclosure will be further described below in detail in combination with FIGS. 6 to 17 and FIGS. 1 to 3. FIGS. 6 to 12 are process flow diagrams showing a method for manufacturing a semiconductor device provided by an embodiment of the disclosure. FIGS. 13 to 16 are process flow diagrams showing a method for manufacturing a semiconductor device provided by another embodiment of the disclosure. FIG. 17 is a process flow diagram showing a method for manufacturing a semiconductor structure provided by yet another embodiment of the disclosure.

First, as shown in FIG. 6, S501 is performed, in which a substrate including a first surface is provided.

The substrate 10 further includes a second surface S2 opposite the first surface S1. The material of the substrate 10 may be an organic insulating material, a fiber-blended organic insulating material, a particle-blended organic insulating material or the like, such as epoxy resin, polyimide, bismaleimide/triazine-based resin, cyanate resin or a composite of glass fiber thereof, or the like, but is not limited thereto. The material of the substrate 10 may also be a semiconductor material such as silicon. In some embodiments, a conductive through-hole (not shown) is formed in the substrate 10.

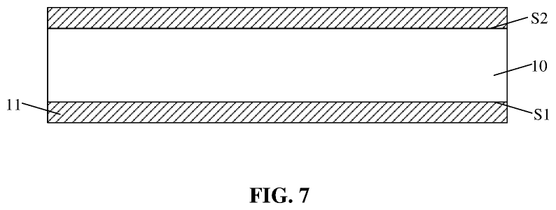

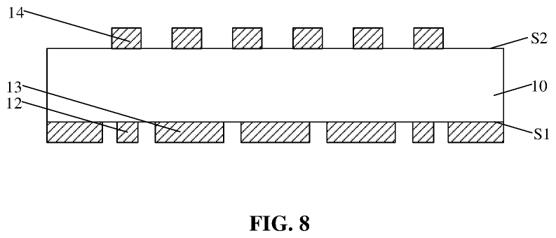

Next, as shown in FIGS. 7 to 8, S502 is performed, in which the first solder pad 12 is formed on the first surface S1.

Specifically, the formation of the first solder pad 12 on the first surface S1 includes the following operations.

A first conductive material layer 11 is formed, in which the first conductive material layer 11 covers at least the first surface S1.

The first conductive material layer 11 covering the first surface S1 is etched to form the first solder pad 12 and transmission lines 13 on the first surface S1.

Referring again to FIGS. 7 to 8, in some embodiments, the formation of the first conductive material layer 11 covering at least the first surface S1 includes forming the first conductive material layer 11 covering the first surface S1 and a second surface S2 of the substrate 10 opposite to the first surface S1.

In a same operation of etching the first conductive material layer 11 covering the first surface S1 to form the first solder pad 12 and the transmission lines 13 on the first surface S1, the method further includes etching the first conductive material layer 11 covering the second surface S2 to form a plurality of second solder pads 14.

Embodiments of the disclosure simplify the process by forming the first solder pad 12 and the second solder pads 14 in a same process. But there is not limited to this, the second solder pads 14 and the first solder pad 12 may also be formed in different processes.

Here, the first conductive material layer 11 may be formed on the first surface S1 and the second surface S2 of the substrate 10 by a process such as chemical vapor deposition (CVD), plasma enhanced CVD (PECVD), physical vapor deposition (PVD), atomic layer deposition (ALD), electroplating, electroless plating, sputtering. The material of the first conductive material layer 11 includes tungsten (W), copper (Cu), titanium (Ti), tantalum (Ta), nickel (Ni), chromium (Cr), gold (Au), silver (Ag), titanium nitride (TiN), tantalum nitride (TaN), a metal silicide, a metal alloy, or any combination thereof, such as copper.

As shown in FIG. 8, there are a plurality of first solder pads 12 and the transmission lines 13 is located between the plurality of first solder pads 12. In some embodiments, the first solder pads 12 and the transmission lines 13 on the first surface S1 are electrically connected with the second solder pads 14 on the second surface S2 through conductive through-holes (not shown) located in the substrate 10.

In some embodiments, the first solder pad 12 is shaped as a cylinder, and the first solder pad 12 has a diameter between 20 μm and 420 μm, and a thickness between 15 μm and 30 μm.

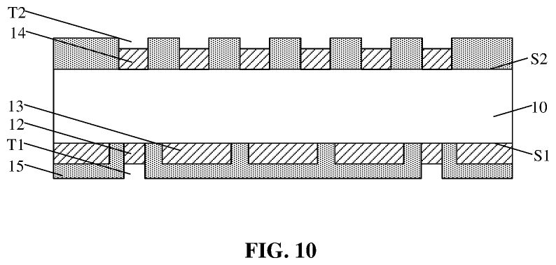

Subsequently, as shown in FIGS. 10 to 12, S503 is performed, in which a transferring part 18 is formed on the first solder pad 12. The transferring part 18 includes a first subpart 181 covering the first solder pad 12 and a second subpart 182 covering the first subpart 181. The orthographic projections of the first subpart 181 and the first solder pad 12 on the first surface S1 fall within the orthographic projection of the second subpart 182 on the first surface S1.

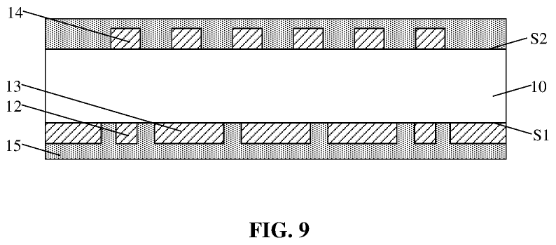

As shown in FIG. 9, in some embodiments, the method further includes, before forming the transferring part 18 on the first solder pad 12, forming a dielectric layer 15 that covers at least the first solder pad 12 and the transmission lines 13 and fills gaps between the first solder pad 12 and the transmission lines 13.

Referring again to FIG. 9, in some embodiments, the formation of the dielectric layer 15 that covers at least the first solder pad 12 and the transmission lines 13 and fills the gap between the first solder pad 12 and the transmission line 13 includes forming a dielectric layer 15 on the first surface S1 and the second surface S2. The dielectric layer 15 also covers a plurality of second solder pads 14 and fills gaps between the plurality of second solder pads 14. Embodiments of the disclosure simplify the process by forming the dielectric layer 15 on the first surface S1 and the second surface S2 in a same process. But there is not limited to this, the dielectric layer 15 on the first surface S1 and the dielectric layer 15 on the second surface S2 may also be formed in different processes. The dielectric layer 15 is used for protecting the first solder pad 12, the transmission lines 13, and the second solder pads 14 from being oxidized or damaged in subsequent processes. The material of the dielectric layer 15 may be graphene, ink, green paint, epoxy resin or the like, for example solder mask (green oil).

Referring again to FIGS. 10 to 12, the formation of the transferring part 18 on the first solder pad 12, the transferring part 18 including a first subpart 181 covering the first solder pad 12 and a second subpart 182 covering the first subpart 181, includes the following operations.

The dielectric layer 15 covering the first solder pad 12 is etched to form a first opening T1, in which the first opening T1 exposes the first solder pad 12.

A second conductive material layer 17 is formed on the first surface S1, in which the second conductive material layer 17 fills the first opening T1 and covers the dielectric layer 15.

Part of the second conductive material layer 17 covering the dielectric layer 15 is etched to form the transferring part 18, in which a part of the transferring part 18 located in the first opening T1 constitutes the first subpart 181, and a part of the transferring part 18 covering the first subpart 181 and part of the dielectric layer 15 constitutes the second subpart 182.

Here, the second conductive material layer 17 may be formed on the first surface S1 of the substrate 10 by a process such as chemical vapor deposition (CVD), plasma enhanced CVD (PECVD), physical vapor deposition (PVD), atomic layer deposition (ALD), electroplating, electroless plating, sputtering. The material of the second conductive material layer 17 includes tungsten (W), copper (Cu), titanium (Ti), tantalum (Ta), nickel (Ni), chromium (Cr), gold (Au), silver (Ag), titanium nitride (TiN), tantalum nitride (TaN), a metal silicide, a metal alloy, or any combination thereof, such as copper.

Referring to FIG. 10 again, in some embodiments, in a same step of etching the dielectric layer 15 covering the first solder pad 12 to form a first opening T1, the first opening T1 exposing the first solder pad 12, the method further includes etching the dielectric layer 15 covering the second solder pads 14 to form second openings T2, the second openings T2 exposing the second solder pads 14. The second solder pads 14 may be used to subsequently be connected to other structures. Embodiments of the disclosure simplify the process by forming the T1 and the T2 in a same process. But there is not limited to this, the first opening T1 and the second opening T2 may also be formed in different operations. In some embodiments, the dielectric layer 15 on the second surface S2 may also be further etched subsequently, so that the upper surface of the dielectric layer 15 is flush with the upper surface of the second solder pads 14, or the dielectric layer 15 located between the plurality of second solder pads 14 may be removed, thus facilitating the connection of the second solder pads 14 to other structures in actual operation, and the embodiments of the disclosure do not limit this too much.

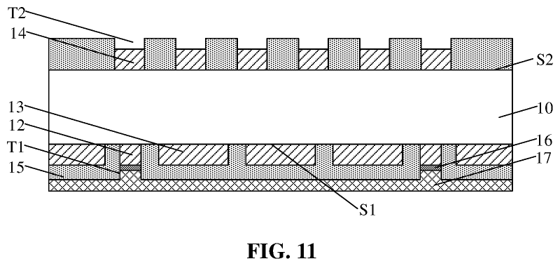

Referring to FIG. 11 again, the method further includes, before forming the second conductive material layer 17 on the first surface S1, forming a composite enhancing layer 16 in the first opening T1. The composite enhancing layer 16 covers the first solder pad 12. The material of the composite enhancing layer 16 may be an alloy material, such as titanium which has the advantages of good electrical conductivity, high strength, easy welding and the like and plays a good bonding role. But there is not limited to this, any material that meets the above requirements may be used as the composite enhancing layer 16 in embodiments of the disclosure.

Next, S504 is performed, in which the solder ball 21 is formed on the second subpart 182 to form a semiconductor structure as shown in FIG. 1 and FIG. 2.

The solder ball 21 may be a lead-containing or lead-free solder ball. In some embodiments, the orthographic projection of the solder ball 21 on the first surface S1 completely coincides with the orthographic projection of the second subpart 182 on the first surface S1, or the orthographic projection of the solder ball 21 on the first surface S1 falls within the orthographic projection of the second subpart 182 on the first surface S1, that is, the cross-sectional dimension of the second subpart 182 is greater than or equal to the cross-sectional dimension of the solder ball 21, which allows the solder ball 21 and the second subpart 182 to have a larger contact area, thereby reducing the contact resistance, and contributing to a firmer soldering of the solder ball 21 to the second subpart 182. In some embodiments, the second subpart 182 is shaped as a cylinder, and the ratio of the diameter of the second subpart 182 to the diameter of the solder ball 21 is between 1 and 1.2, for example, is 1.1. In some embodiments, the second subpart 182 has a diameter between 40 μm and 510 μm and a thickness between 10 μm and 20 μm. The solder ball 21 has a diameter between 40 μm and 420 μm.

Referring again to FIG. 1 or FIG. 2, in some embodiments, the method further includes, before forming the solder ball 21, forming a solderable layer 19 covering a surface of the second subpart 182 to be electrically connected to the solder ball 21. The solderable layer 19 facilitates a firmer soldering of the solder ball 21 to the second subpart 182. The material of the side of the solderable layer 19 to be electrically connected to the solder ball 21 may be tin (Sn), gold (Au) or silver (Ag).

The first subpart 181 of the transferring part 18 shown in FIGS. 12 and 1 to 2 is formed in the first opening T1, and the height H1 of the first subpart 181 is equal to or less than the height H2 of the first opening T1. In some embodiments of the present disclosure, the first subpart 181 is only partially formed in the first opening T1, and the height H1 of the first subpart 181 is greater than the height H2 of the first opening T1, as shown in FIGS. 13 to 16 and 3.

Specifically, as shown in FIG. 13, after the dielectric layer 15 covering at least the first solder pad 12 and the transmission lines 13 and filling the gap between the first solder pad 12 and the transmission line 13 is formed, the method further includes, after forming the dielectric layer 15 covering at least the first solder pad 12 and the transmission lines 13 and filling the gap between the first solder pad 12 and the transmission line 13, forming an insulating layer 25 covering the dielectric layer 15 on the first surface S1. In the subsequent process, after the transferring part 18 is formed, the insulating layer 25 is removed. Therefore, the etching rate of the insulating layer 25 is greater than the etching rate of the dielectric layer 15 under a preset etching condition.

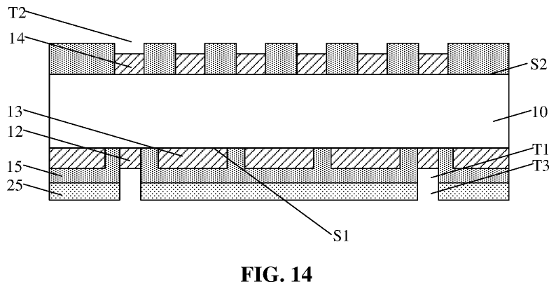

Next, as shown in FIG. 14, the insulating layer 25 covering the dielectric layer 15 and the dielectric layer 15 covering the first solder pad 12 are etched to form a third opening T3 and a first opening T1 respectively. The third opening T3 and the first opening T1 expose the first solder pad 12.

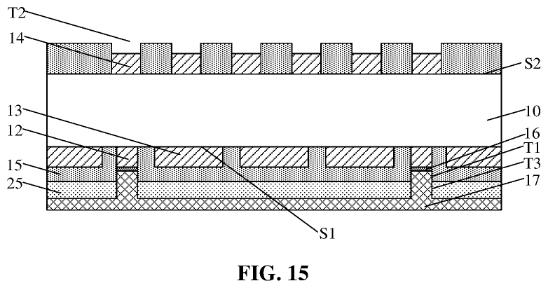

Next, as shown in FIG. 15, a second conductive material layer 17 is formed on the first surface S1. The second conductive material layer 17 fills the first opening T1 and the third opening T3 and covers the insulating layer 25.

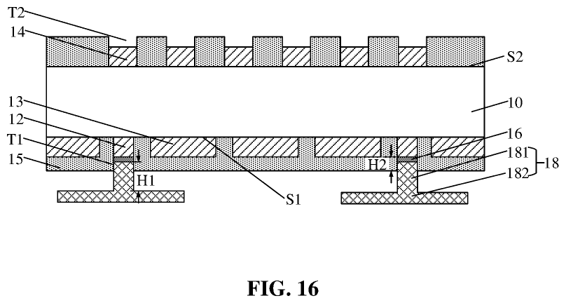

Next, as shown in FIG. 16, part of the second conductive material layer 17 covering the insulating layer 25 is etched to form the transferring part 18. A part of the transferring part 18 located in the first opening T1 and the third opening T3 constitutes the first subpart 181, and a part of the transferring part 18 covering the first subpart 181 and part of the insulating layer 25 constitutes the second subpart 182.

Next, the insulating layer 25 is removed and the solder ball 21 is formed on the second subpart 182 to form a semiconductor structure as shown in FIG. 3.

In this embodiment, the first subpart 181 is partially located in the first opening T1, the height H1 of the first subpart 181 is greater than the height H2 of the first opening T1. The second subpart 182 is farther from the transmission line 13, so that the signal interference between the second subpart 182 and the transmission line 13 can be reduced when the semiconductor structure is in operation.

In the above embodiments, the transferring part 18 is formed on the first solder pad 12 by first forming a second conductive material layer 17 covering the first solder pad 12, and then etching the second conductive material layer 17 to form the transferring part 18. But there is not limited to this, as shown in FIG. 17, in yet another embodiment of the disclosure, the formation of the transferring part 18 on the first solder pad 12 includes: etching the dielectric layer 15 covering the first solder pad 12 to form a first opening T1, in which the first opening T1 exposes the first solder pad 12; providing a transferring part 18 including a first subpart 181 and a second subpart 182 covering the first subpart 181; and soldering the first subpart 181 of the transferring part 18 to the first solder pad 12.

In some embodiments, the method further includes: before the first subpart 181 of the transferring part 18 is soldered to the first solder pad 12, a composite enhancing layer 16 covering the first subpart 181 is formed, and the transferring part 18 is soldered to the first solder pad 12 through the composite enhancing layer 16. The composite enhancing layer 16 plays a good connection role.

It can be seen that, in the embodiments of the disclosure, the solder ball 21 is soldered to the second subpart 182 and the first solder pad 12 is connected to the first subpart 181. Without changing the size of the solder ball 21, the area occupied by the first solder pad 12 on the first surface S1 can be reduced by reducing the size of the first solder pad 12, thereby allowing the transmission lines 13 to occupy a larger area on the first surface S1. Thus, the transmission lines 13 can be designed to be wider, so that the breakage risk of transmission line 13 is reduced or eliminated, avoiding electromagnetic interference and signal crosstalk caused by a too close distance of the transmission lines. In addition, the problem of long transmission path of the transmission lines 13 can be avoided or alleviated due to the small size of the first solder pad 12.

It should be noted that those skilled in the art can change the step sequence described above without departing from the protection scope of the present disclosure. The description above is only optional embodiments of the disclosure, and is not intended to limit the protection scope of the present disclosure. Any modification, equivalent replacement or improvement and the like made within the spirit and principle of the disclosure shall fall within the protection scope of the disclosure.

In the semiconductor structure, the packaging device and the method for manufacturing a semiconductor structure provided by the embodiments of the disclosure, the semiconductor structure includes a substrate including a first surface; a first solder pad located on the first surface; a transferring part located on the first solder pad, in which the transferring part includes a first subpart covering the first solder pad and a second subpart covering the first subpart, and orthographic projections of the first subpart and the first solder pad on the first surface fall within the orthographic projection of the second subpart on the first surface; and a solder ball located on the second subpart. The solder ball is electrically connected with the first solder pad through the transferring part, and the solder ball is located on the second subpart having a larger size. In this way, without changing the size of the solder ball, the area occupied by the first solder pad on the surface of the substrate can be reduced by reducing the size of the first solder pad, thereby allowing the transmission lines to occupy a larger area on the surface of the substrate. Thus, the transmission lines can be designed to be wider, so that the breakage risk of transmission line is reduced or eliminated, avoiding electromagnetic interference and signal crosstalk caused by a too close distance of the transmission lines. In addition, the problem of long transmission path of the transmission lines can be avoided or alleviated due to the small size of the first solder pad.

What is claimed is:

1. A semiconductor structure, comprising:
a substrate comprising a first surface;
a first solder pad located on the first surface;
a transferring part located on the first solder pad, and comprising a first subpart covering the first solder pad and a second subpart covering the first subpart, wherein orthographic projections of the first subpart and the first solder pad on the first surface fall within an orthographic projection of the second subpart on the first surface; and
a solder ball located on the second subpart.

2. The semiconductor structure of claim 1, wherein an orthographic projection of the solder ball on the first surface completely coincides with the orthographic projection of the second subpart on the first surface, or the orthographic projection of the solder ball on the first surface falls within the orthographic projection of the second subpart on the first surface.

3. The semiconductor structure of claim 1, wherein the orthographic projection of the first subpart on the first surface completely coincides with the orthographic projection of the first solder pad on the first surface, or the orthographic projection of the first subpart on the first surface falls within the orthographic projection of the first solder pad on the first surface.

4. The semiconductor structure of claim 1, wherein a width of the first subpart gradually increases in a direction perpendicular to the first surface and from the first solder pad to the second subpart.

5. The semiconductor structure of claim 1, further comprising: a composite enhancing layer located between the first subpart and the first solder pad.

6. The semiconductor structure of claim 1, further comprising: a solderable layer located between the solder ball and the second subpart.

7. The semiconductor structure of claim 1, further comprising: transmission lines located on the first surface; and a dielectric layer covering the transmission lines and filling a gap between the first solder pad and the transmission line, wherein a first opening exposing the first solder pad is formed in the dielectric layer, the first subpart is located in the first opening, and the second subpart covers the first subpart and part of the dielectric layer.

8. The semiconductor structure of claim 7, further comprising: a plurality of second solder pads located on a second surface of the substrate opposite to the first surface, wherein the dielectric layer further fills gaps between the plurality of second solder pads, and a plurality of second openings are formed in the dielectric layer, and wherein the second openings expose the second solder pads.

9. A packaging device, comprising: at least one chip, and the semiconductor structure of claim 1, wherein the at least one chip is bonded to the semiconductor structure.

10. A manufacturing method of a semiconductor structure, comprising:
providing a substrate comprising a first surface;
forming a first solder pad on the first surface;
forming a transferring part on the first solder pad, the transferring part comprising a first subpart covering the first solder pad and a second subpart covering the first subpart, wherein orthographic projections of the first subpart and the first solder pad on the first surface fall within an orthographic projection of the second subpart on the first surface; and
forming a solder ball on the second subpart.

11. The manufacturing method of claim 10, wherein forming the first solder pad on the first surface comprises:
forming a first conductive material layer covering at least the first surface; and
etching the first conductive material layer covering the first surface to form the first solder pad and transmission lines on the first surface.

12. The manufacturing method of claim 11, further comprising: before forming the transferring part on the first solder pad,
forming a dielectric layer covering at least the first solder pad and the transmission lines and filling a gap between the first solder pad and the transmission line.

13. The manufacturing method of claim 12, wherein forming the transferring part on the first solder pad, the transferring part comprising the first subpart covering the first solder pad and the second subpart covering the first subpart, comprises:
etching the dielectric layer covering the first solder pad to form a first opening exposing the first solder pad;
forming a second conductive material layer on the first surface, wherein the second conductive material layer fills the first opening and covers the dielectric layer; and
etching part of the second conductive material layer covering the dielectric layer to form the transferring part, wherein a part of the transferring part located in the first opening constitutes the first subpart, and a part of the transferring part covering the first subpart and part of the dielectric layer constitutes the second subpart.

14. The manufacturing method of claim 13, further comprising: before forming the second conductive material layer on the first surface, forming a composite enhancing layer in the first opening, wherein the composite enhancing layer covers the first solder pad.

15. The manufacturing method of claim 14, further comprising: before forming the solder ball, forming a solderable layer covering a surface of the second subpart to be electrically connected to the solder ball.

16. The manufacturing method of claim 12, wherein forming the first conductive material layer covering at least the first surface comprises: forming the first conductive material layer covering the first surface and a second surface of the substrate opposite to the first surface; and
the method further comprises: in a same operation of etching the first conductive material layer covering the first surface to form the first solder pad and the transmission lines on the first surface, etching the first conductive material layer covering the second surface to form a plurality of second solder pads.

17. The manufacturing method of claim 16, wherein forming the dielectric layer covering at least the first solder pad and the transmission lines and filling the gap between the first solder pad and the transmission line comprises:
forming the dielectric layer on the first surface and the second surface, wherein the dielectric layer further covers the plurality of second solder pads and fills gaps between the plurality of second solder pads.

18. The manufacturing method of claim 17, further comprising: in a same operation of etching the dielectric layer covering the first solder pad to form the first opening exposing the first solder pad,
etching the dielectric layer covering the second solder pads to form second openings exposing the second solder pads.
